(19) United States
(12) Patent Application Publication
(10) Pub. No.: US 2024/0292593 A1
(43) Pub. Date: Aug. 29, 2024

(54) SEMICONDUCTOR-ELEMENT-INCLUDING MEMORY DEVICE

(71) Applicant: Unisantis Electronics Singapore Pte. Ltd., Singapore (SG)

(72) Inventors: Koji SAKUI, Tokyo (JP); Masakazu Kakumu, Tokyo (JP); Nozomu Harada, Tokyo (JP)

(21) Appl. No.: 18/585,378

(22) Filed: Feb. 23, 2024

(30) Foreign Application Priority Data
Feb. 24, 2023 (WO) PCT/JP2023/006662

(51) Int. Cl. H10B 12/00; G11C 11/404; G11C 11/4096

(52) U.S. Cl. CPC H10B 12/20; G11C 11/404; G11C 11/4096

(57) ABSTRACT

A memory device includes, on a substrate in plan view, at least one memory array including: multiple pages, each including multiple memory cells arranged in a row direction; and multiple bit lines disposed in a column direction and connected to the memory cells. A first impurity layer lies on part of the substrate and extends in a vertical direction, a first semiconductor layer lies thereon, and a first gate insulating layer coats side walls of the layers. A first gate conductor layer connected to a plate line and a second insulating layer are in a groove. A second semiconductor layer lies on the first semiconductor layer, and an n+ layer connected to a source line and an n+ layer connected to a bit line are at both ends thereof. A second gate insulating layer coats the second semiconductor layer. A second gate conductor layer is connected to a word line.

### CROSS-REFERENCE TO RELATED APPLICATIONS

This application claims priority to PCT/JP2023/006662, filed Feb. 24, 2023, the entire content of which is incorporated herein by reference.

### BACKGROUND OF THE INVENTION

### 1. Field of the Invention

The present invention relates to a semiconductor-element-including memory device.

### 2. Description of the Related Art

Recent development of large scale integration (LSI) technology requires high integration, high performance, low power consumption, and high functionality of memory elements.

Typical planar metal oxide semiconductor (MOS) transistors have a channel extending in a horizontal direction along an upper surface of a semiconductor substrate. In contrast, surrounding gate transistors (SGTs) have a channel extending in a direction perpendicular to an upper surface of a semiconductor substrate (see, for example, Japanese Unexamined Patent Application Publication No. 3-171768 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). With this configuration, the SGTs enable an increase in the density of semiconductor devices, compared with the planar MOS transistors. Such SGTs can be used as selection transistors to implement high-integration memories such as a dynamic random access memory (DRAM) (see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) to which a capacitor is connected, a phase change memory (PCM) (see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No 12, December, pp. 2201-2227 (2010)) to which a resistance change element is connected, a resistive random access memory (RRAM) (see, for example, T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007)), and a magneto-resistive random access memory (MRAM) (see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)) in which a change in magnetic spin orientation is induced by current to change resistance. Also available are a capacitor-less DRAM memory cell including a single MOS transistor (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)) and a DRAM memory cell having two groove portions for storing carriers and two gate electrodes (see Md. Hasan Raza Ansari, Nupur Navlakha, Jae Yoon Lee, Seongjae Cho, “Double-Gate Junctionless 1T DRAM With Physical Barriers for Retention Improvement”, IEEE Trans, on Electron Devices vol. 67, pp. 1471-1479 (2020)), for example. However, capacitor-less DRAMs have a problem in that such DRAMs are greatly affected by, in the floating bodies, coupling of gate electrodes due to word lines and a sufficient voltage margin is difficult to achieve. A complete depletion of the substrate makes the problem worse. This application relates to a semiconductor-element-including memory device that can be constituted by MOS transistors alone and that includes no resistance change elements or capacitors.

A capacitor-less single-transistor DRAM (gain cell) in a memory device has a problem in that the capacitive coupling between the word line and the body including an element in a floating state is large, and a change in the potential of the word line during reading or writing of data is directly transmitted as noise to the body of a semiconductor substrate. This causes a problem of erroneous reading or erroneous rewriting of stored data and makes it difficult to put a capacitor-less single-transistor DRAM into practical use. In addition to addressing the problems described above, it is desirable to achieve high density of DRAM memory cells.

Other examples of the related art include US2008/0137394 A1, US2003/0111681 A1, and Japanese Patent No. 7057032.

### SUMMARY OF THE INVENTION

To address the problems described above, according to a first aspect of the present invention, a semiconductor-element-including memory device includes a memory cell array. The memory cell array includes a plurality of pages connected to a bit line disposed on a substrate in a column direction in plan view. Each of the plurality of pages includes a plurality of memory cells arranged on the substrate in a row direction in plan view. Each of the memory cells included in each of the plurality of pages includes a first impurity layer on top of the substrate; a first insulating layer covering the substrate and a portion of the first impurity layer; a first semiconductor layer having a pillar shape and extending in a direction perpendicular to the first impurity layer in contact with the first impurity layer; a first gate insulating layer surrounding the first semiconductor layer; a first gate conductor layer covering the first gate insulating layer; a second insulating layer on top of the first gate conductor layer; a second semiconductor layer on top of and in contact with the first semiconductor layer; a second gate insulating layer surrounding at least a top portion of the second semiconductor layer; a second gate conductor layer covering the second gate insulating layer; a second impurity layer; and a third impurity layer, the second impurity layer and the third impurity layer being connected to both ends of the second semiconductor layer in a horizontal direction in which the second semiconductor layer extends, the both ends of the second semiconductor layer being outside one end of the second gate conductor layer. In a page erase operation, majority carriers remaining in the first semiconductor layer or the second semiconductor layer are extracted by being recombined with majority carriers in the first impurity layer, the second impurity layer, and the third impurity layer. In a page write operation, an electron group and a hole group are generated in the second semiconductor layer and the first semiconductor layer by using a gate-induced drain leakage current or by using an impact ionization phenomenon caused by a current flowing between the second impurity layer and the third impurity layer, and an operation of causing some or all of majority carriers in the second semiconductor layer and the first semiconductor layer to remain in the second semiconductor layer and the first semiconductor layer is performed. In a page read operation, an operation of causing some of the majority carriers in the second semiconductor layer and the first semiconductor layer to move from the first semiconductor layer to the second semiconductor layer is performed to determine an erase state or a write state of the memory cell, based on a magnitude of a memory cell current between the bit line and a source line of the memory cell.

According to a second aspect of the present invention, in the first aspect described above, the second impurity layer is connected to the source line, the third impurity layer is connected to the bit line, the second gate conductor layer is connected to a word line, and the first gate conductor layer is connected to a plate line.

According to a third aspect of the present invention, in the second aspect described above, the page erase operation, the page write operation, and the page read operation are performed by controlling voltages to be applied to the source line, the bit line, the word line, and the plate line.

According to a fourth aspect of the present invention, in the second aspect described above, a first voltage is applied to the plate line at a time of retention of data in the memory cell, and a second voltage higher than the first voltage is applied to the plate line at a time of the page read operation.

According to a fifth aspect of the present invention, in the fourth aspect described above, a ground voltage is applied to the source line, the bit line, and the word line at the time of retention of data in the memory cell.

According to a sixth aspect of the present invention, in the second aspect described above, in the page erase operation, a first positive voltage is applied to the plate line.

According to a seventh aspect of the present invention, in the second aspect described above, in the page write operation, a first negative voltage is applied to the word line.

According to an eighth aspect of the present invention, in the first aspect described above, in the page write operation, a second positive voltage is applied to the bit line.

According to a ninth aspect of the present invention, in the second aspect described above, in the page read operation, a third positive voltage is applied to the word line, and a fourth positive voltage is applied to the bit line.

According to a tenth aspect of the present invention, in the first aspect described above, a vertical distance from a bottom portion of the second semiconductor layer to a top portion of the first impurity layer is shorter than a vertical distance from the bottom portion of the second semiconductor layer to a bottom portion of the first gate conductor layer.

According to an eleventh aspect of the present invention, in the first aspect described above, the source line connected to the second impurity layer of one of the plurality of memory cells is shared with the second impurity layer of an adjacent memory cell of the plurality of memory cells.

According to a twelfth aspect of the present invention, in the first aspect described above, the bit line connected to the third impurity layer of one of the plurality of memory cells is shared with the third impurity layer of an adjacent memory cell of the plurality of memory cells.

According to a thirteenth aspect of the present invention, in the fifth aspect described above, the ground voltage is zero volts.

According to a fourteenth aspect of the present invention, in the first aspect described above, a bottom portion of the first impurity layer is not at a same level as a bottom portion of the first insulating layer, and the first impurity layer is shared by the plurality of memory cells.

According to a fifteenth aspect of the present invention, in the second aspect described above, a bottom line is connected to the first impurity layer, and a desired voltage is applicable to the bottom line.

According to a sixteenth aspect of the present invention, in the second aspect described above, in the page erase operation, a second negative voltage is applied to the source line, and a fifth positive voltage is applied to the word line.

According to a seventeenth aspect of the present invention, in the fifteenth aspect described above, in the page erase operation, a third negative voltage is applied to the bottom line.

According to an eighteenth aspect of the present invention, in the fifteenth aspect described above, a third voltage is applied to the bottom line at a time of retention of data in the memory cell, and a fourth voltage higher than the third voltage is applied at a time of the page read operation.

According to a nineteenth aspect of the present invention, in the seventeenth aspect described above, the source line, the word line, the plate line, and the bottom line are arranged in parallel in the row direction and are included in each of the plurality of pages, and the bit line arranged in the column direction is orthogonal to the page.

According to a twentieth aspect of the present invention, in the first aspect described above, in the page write operation, a DC current between the bit line and the source line is zero.

According to a twenty first aspect of the present invention, in the first aspect described above, in the page erase operation, capacitive coupling between the first gate conductor layer and the first semiconductor layer raises a voltage of the first semiconductor layer.

### BRIEF DESCRIPTION OF THE DRAWINGS

FIG. 1A is a sectional structural view of a semiconductor-element-including memory device according to a first embodiment.

FIG. 1BA is a plan view of a memory device including a 2×2 matrix of memory cells, each illustrated in FIG. 1A, and FIGS. 1BB and 1BC are sectional structural views of the memory device illustrated in FIG. 1BA.

FIGS. 2A, 2B, 2C, and 2D are views for describing a write operation, storage of carriers immediately after the operation, and a cell current in the semiconductor-element-including memory device according to the first embodiment.

FIGS. 3A, 3B, and 3C are views for describing storage of hole carriers immediately after the write operation, an erase operation, and the cell current in the semiconductor-element-including memory device according to the first embodiment.

FIG. 4A is a view for describing an operation method of the semiconductor-element-including memory device according to the first embodiment.

FIG. 4B is a view for describing an operation method of the semiconductor-element-including memory device according to the first embodiment.

FIG. 4C is a view for describing an operation method of the semiconductor-element-including memory device according to the first embodiment.

FIG. 4D is a view for describing an operation method of the semiconductor-element-including memory device according to the first embodiment.

FIG. 4E is a view for describing an operation method of the semiconductor-element-including memory device according to the first embodiment.

FIG. 4F is a view for describing an operation method of the semiconductor-element-including memory device according to the first embodiment.

FIG. 4G is a view for describing an operation method of the semiconductor-element-including memory device according to the first embodiment.

FIG. 4H is a view for describing an operation method of the semiconductor-element-including memory device according to the first embodiment.

### DESCRIPTION OF THE PREFERRED EMBODIMENTS

Hereinafter, the structure of a semiconductor-element-including memory device according to an embodiment of the present invention, a driving method thereof, and the behavior of carriers stored therein will be described with reference to the drawings.

### First Embodiment

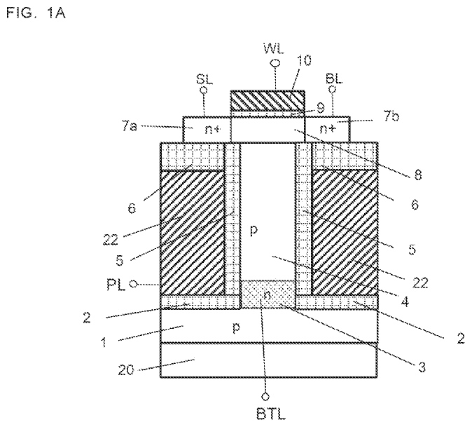

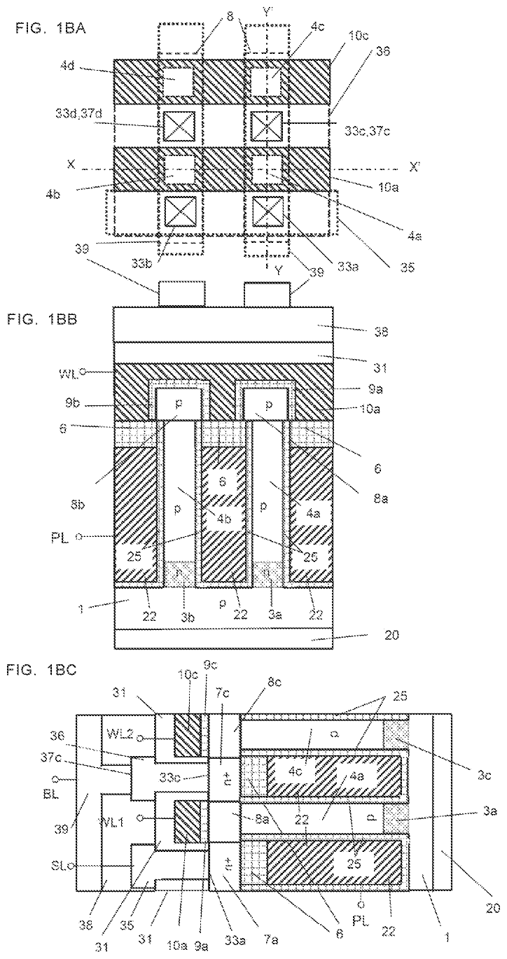

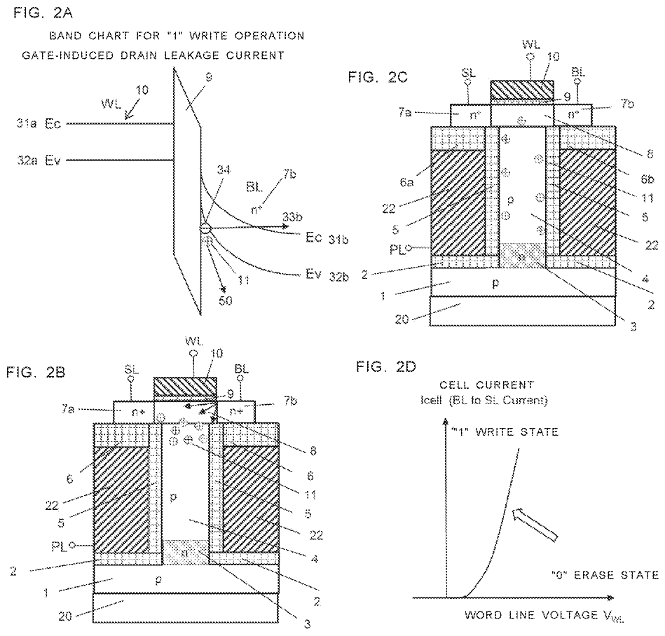

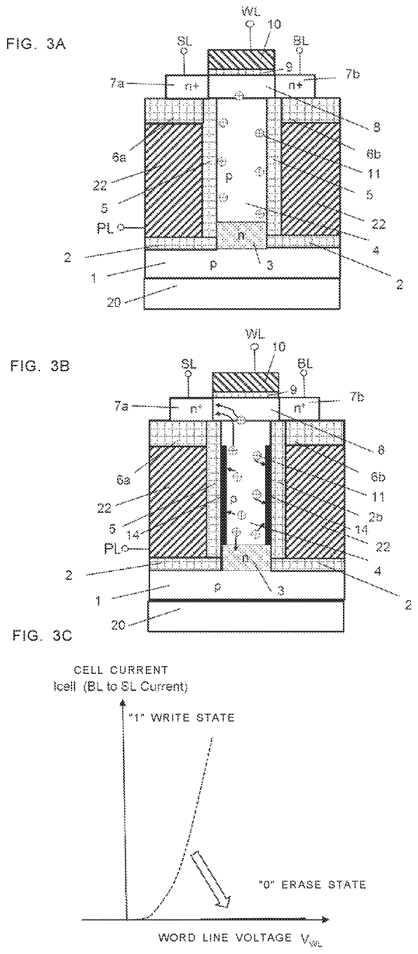

The structure and operation mechanism of a semiconductor-element-including memory cell according to a first embodiment of the present invention will be described with reference to FIGS. 1A, 1BA to 1BC, 2A to 2D, and 3A to 3C. The structure of the semiconductor-element-including memory cell according to the present embodiment will be described with reference to FIG. 1A. The structure of the memory cell will be described in detail with reference to FIGS. 1BA to 1BC. A data writing mechanism of the semiconductor-element-including memory cell and the behavior of carriers for will be described with reference to FIGS. 2A to 2D. A data erasing mechanism of the semiconductor-element-including memory cell will be described with reference to FIGS. 3A to 3C.

FIG. 1A illustrates a vertical sectional structure of the semiconductor-element-including memory cell according to the first embodiment of the present invention. Here, a dynamic flash memory element will be described in terms of an SGT including a first gate insulating layer 5 and a first gate conductor layer 22, by way of example. The first gate insulating layer 5 surrounds an entire side surface of a p layer 4 standing on a substrate in a direction perpendicular to the substrate. A substrate 20 has on top thereof a p layer 1 made of silicon containing an acceptor impurity and having a p conductivity type. A semiconductor includes a pillar-shaped n layer 3 (an example of “first impurity layer” in the claims) standing on a surface of the p layer 1 in a direction perpendicular to the surface of the p layer 1 and containing a donor impurity. On top of the semiconductor, a pillar-shaped p layer 4 (an example of “first semiconductor layer” in the claims) containing an acceptor impurity is disposed. A first insulating layer 2 covers the p layer 1 and a portion of the n layer 3. The first gate insulating layer 5 covers the p layer 4. The first gate conductor layer 22 is in contact with the first insulating layer 2 and the first gate insulating layer 5. A second insulating layer 6 is in contact with the first gate insulating layer 5 and the first gate conductor layer 22. A p layer 8 (an example of “second semiconductor layer” in the claims) containing an acceptor impurity is in contact with the p layer 4.

An n+ layer 7a (an example of “second impurity layer” in the claims) is disposed on one side of the p layer 8. The n+ layer 7a contains a high-concentration donor impurity. An n+ layer 7b (an example of “third impurity layer” in the claims) is disposed on the other side of the p layer 8 farther away from the n+ layer 7a.

A second gate insulating layer 9 is disposed on an upper surface of the p layer 8. The second gate insulating layer 9 is in contact with or in close proximity to the n+ layers 7a and 7b. A second gate conductor layer 10 is disposed on a side of the second gate insulating layer 9 farther away from the semiconductor layer 8, in contact with the second gate insulating layer 9.

Accordingly, the substrate 20, the p layer 1, the first insulating layer 2, the first gate insulating layer 5, the first gate conductor layer 22, the second insulating layer 6, the n layer 3, the p layer 4, the n+ layer 7a, the n+ layer 7b, the p layer 8, the second gate insulating layer 9, and the second gate conductor layer 10 form a semiconductor-element-including memory cell. The n+ layer 7a is connected to a source line SL. The n+ layer 7b is connected to a bit line BL. The second gate conductor layer 10 is connected to a word line WL. The first gate conductor layer 22 is connected to a plate line PL. The n layer 3 is connected to a bottom line BTL (an example of “bottom line” in the claims). Potentials to be supplied to the source line SL, the bit line BL, the plate line PL, the word line WL, and the bottom line BTL are controlled to perform memory operations. A memory device including the memory cell described above is hereafter referred to as a dynamic flash memory.

In the memory device according to the present embodiment, one dynamic flash memory or a two-dimensional array of dynamic flash memories, each dynamic flash memory having been described above, are disposed on the substrate 20.

While the p layer 1 is made of p-type semiconductor in FIG. 1A, its impurity concentration may have a profile. The impurity concentrations of the n layer 3, the p layer 4, and the p layer 8 may have profiles. The impurity concentrations and profiles of the p layer 4 and the p layer 8 may be set independently.

When the n+ layer 7a and the n+ layer 7b are formed as p+ layers having holes as majority carriers, the p layer 1, the p layer 4, the p layer 8 are made of n-type semiconductor, the n layer 3 is made of p-type semiconductor, the first gate conductor layer 22 is made of a material having a work function lower than the work function of the second gate conductor layer 10, and the operation of the dynamic flash memory is performed with the carriers for writing being electrons.

In FIG. 1A, the p layer 1 is made of p-type semiconductor. Alternatively, the substrate 20 is an n-type semiconductor substrate, and a p-well is formed and used as the p layer 1 to form a memory cell according to an embodiment of the present invention. With this configuration, the operation of a dynamic flash memory is also performed.

In FIG. 1A, the first insulating layer 2 and the first gate insulating layer 5 are illustrated as separate layers. Alternatively, the first insulating layer 2 and the first gate insulating layer 5 may be formed into a single layer. In the following description, the first insulating layer 2 and the first gate insulating layer 5 are collectively referred to as the first gate insulating layer 5.

In FIG. 1A, the second semiconductor layer 8 is made of p-type semiconductor. Alternatively, the second semiconductor layer 8 may be of any type among a p-type, an n-type, and an i-type, depending on the majority carrier concentration of the p layer 4, the thickness of the second semiconductor layer 8, the material and thickness of the second gate insulating layer 9, and the material of the second gate conductor layer 10.

In FIG. 1A, a bottom portion of the p layer 8 and an upper surface of the second insulating layer 6 are illustrated at the same level. However, the interface between the p layer 4 and the p layer 8 need not be at the same level as the upper surface of the second insulating layer 6 as long as the p layer 4 and the p layer 8 are in contact with each other and a bottom portion of the p layer 4 is located at a deeper position than a bottom portion of the second insulating layer 6.

Further, the vertical distance from the bottom portion of the second semiconductor layer 8 to the top portion of the first impurity layer 3 is shorter than the vertical distance from the bottom portion of the second semiconductor layer 8 to a bottom portion of the first gate conductor layer 22.

The substrate 20 may be made of any material such as an insulator, a semiconductor, or a conductor as long as the substrate 20 supports the p layer 1.

The first gate conductor layer 22 may be a semiconductor layer doped at a high concentration or a conductor layer as long as the first gate conductor layer 22 is configured to change the potential of a portion of the memory cell through the first insulating layer 2 or the first gate insulating layer 5.

In the memory cell, the metal oxide semiconductor field-effect transistor (MOSFET) operates while including, as constituent elements, the n+ layer 7a serving as the source, the n+ layer 7b serving as the drain, the second gate insulating layer 9, the second gate conductor layer 10 serving as the gate, and the p layer 8 serving as the substrate. The MOSFET may be implemented as a fin field-effect transistor (FinFET) (see H. Jiang, N. Xu, B. Chen, L. Zeng1, Y. He, G. Du, X. Liu and X. Zhang: “Experimental investigation of self heating effect (SHE) in multiple-fin SOI FinFETs”, Semicond. Sci. Technol. 29 (2014) 115021 (7pp)), a gate-all-around (GAA) transistor (see J. Y. Song, W. Y. Choi, J. H. Park, J. D. Lee, and B-G. Park: “Design Optimization of Gate-All-Around (GAA) MOSFETS”, IEEE Trans. Electron Devices, vol. 5, no. 3, pp. 186-191, May 2006), or a Nanosheet transistor (see N. Loubet, et al.: “Stacked Nanosheet Gate-All-Around Transistor to Enable Scaling Beyond FinFET”, 2017 IEEE Symposium on VLSI Technology Digest of Technical Papers, T17-5, T230-T231, June 2017).

In FIG. 1A, a bottom portion of the n layer 3 and a bottom portion of the first insulating layer 2 are illustrated at the same level. However, the bottom portion of the n layer 3 and the bottom portion of the first insulating layer 2 need not be at the same level. The n layer 3 may be extended into the p layer 1. Alternatively, the n layer 3 may be extended over the p layer 1 and connected to an adjacent memory cell. The n layer 3 may be connected to an electrode to which a voltage is to be applied.

FIGS. 1BA to 1BC illustrate a memory cell array having a 2×2 matrix of memory cells, each of which is illustrated in FIG. 1A. The structure of the dynamic flash memory according to the present embodiment will be described in more detail with reference to FIGS. 1BA to 1BC. FIG. 1BA is a plan view of the dynamic flash memory. FIG. 1BB is a vertical sectional view of the dynamic flash memory taken along line X-X′ of FIG. 1BA. FIG. 1BC is a vertical sectional view of the dynamic flash memory taken along line Y-Y′ of FIG. 1BA. In FIGS. 1BA to 1BC, components that are the same as or similar to those illustrated in FIG. 1A are denoted by the same reference numerals.

In FIGS. 1BA to 1BC, an insulating layer 31 is provided with contact holes 33a to 33d for the respective memory cells, and the memory cells are connected to a source line SL35. The source line SL35 is covered with an insulating film 38, and the insulating film 38 is provided with second contact holes 37c and 37d. The memory cells are connected to bit lines BL39.

Correspondences between the components illustrated in FIG. 1A and the components illustrated in FIGS. 1BA to 1BC are as follows: n layer 3 (FIG. 1A)/n layer 3a (FIGS. 1BA to 1BC); p layer 4 (FIG. 1A)/p layer 4a (FIGS. 1BA to 1BC); semiconductor layer 8 (FIG. 1A)/semiconductor layer 8a (FIGS. 1BA to 1BC); n+ layer 7a (FIG. 1A)/n+ layer 7a (FIGS. 1BA to 1BC) connected to the source line SL; n+ layer 7b (FIG. 1A)/n+ layer 7c (FIGS. 1BA to 1BC) connected to the bit lint BL; second gate insulating layer 9 (FIG. 1A)/second gate insulating layer 9a (FIGS. 1BA to 1BC); second gate conductor layer 10 (FIG. 1A)/second gate conductor layer 10a (FIGS. 1BA to 1BC) connected to the word line WL; and first gate conductor layer 22 (FIG. 1A)/first gate conductor layer 22 (FIGS. 1BA to 1BC) connected to the plate line PL.

Further, in FIGS. 1BA to 1BC, the grooves are illustrated as vertical cross sections having a rectangular shape. The vertical cross sections of the grooves may have a trapezoidal shape. In addition, the n layer (first impurity layer) 3 and the p layer (first semiconductor layer) 4 are illustrated as having a pillar shape with a quadrangular bottom surface, but may have a pillar shape with a non-quadrangular bottom surface such as a polygonal bottom surface or a circular bottom surface.

The carrier behavior, storage, and the cell current at the time of the data write operation of the dynamic flash memory according to the first embodiment of the present invention will be described with reference to FIG. 2A to 2D. First, the following case will be described. The majority carriers of the n+ layer 7a and the n+ layer 7b are electrons. For example, the first gate conductor layer 22 connected to the plate line PL is made of poly Si containing an acceptor impurity at a high concentration. The poly Si containing an acceptor impurity at a high concentration is hereafter referred to as “p+ poly”. The second gate conductor layer 10 connected to the word line WL is made of poly Si containing a donor impurity at a high concentration. The poly Si containing a donor impurity at a high concentration is hereinafter referred to as “n+ poly”. The second semiconductor layer 8 is made of p-type semiconductor. As illustrated in FIG. 2B, the MOSFET in the memory cell operates while including, as constituent elements, the n+ layer 7a serving as the source, the n+ layer 7b serving as the drain, the second gate insulating layer 9, the second gate conductor layer 10 serving as the gate, and the p layer 8 serving as the substrate. For example, 0 V is applied to the p layer 1, and a ground voltage of, for example, zero volts (0 V) is applied to the n+ layer 7a connected to the source line SL. Further, a first voltage to be applied at the time of retention of data in the memory cell, which is, for example, −1 V, is applied to the first gate conductor layer 22 connected to the plate line PL. A ground voltage of, for example, 0 V may be input to the plate line PL. For example, 1.5 V is input to the n+ layer 7b connected to the bit line BL, and a first negative voltage is applied to the second gate conductor layer 10 connected to the word line WL. The first negative voltage and the first voltage may be set to the same voltage, for example, −1 V, which leads to the advantage of simple circuit design.

A mechanism for a page write operation will be described with reference to FIGS. 2A to 2D. FIG. 2A is a band chart illustrating a mechanism for generating a gate-induced drain leakage current. When the voltage to be applied to the n+ layer 7b serving as the third impurity layer connected to the bit line BL is set to be higher than the voltage to be applied to the second gate conductor layer 10 connected to the word line WL, a gate-induced drain leakage (GIDL) current (see E. Yoshida, T. Tanaka, “A Capacitorless 1 T-DARM Technology Using Gate-Induced Drain-Leakage (GIDL) Current for Low-Power and High-Speed Embedded Memory”, IEEE Trans, on Electron Devices vol. 53, pp. 692-697 (2006)) flows. This is because a strong electric field between the second gate conductor layer 10 and the n+ layer 7b serving as the third impurity layer bends a valence band 32b and a conduction band 31b between the second semiconductor layer 8 and the n+ layer 7b serving as the third impurity layer. In band-to-band tunneling 33b, an electron group 34 tunnels to the valence band 32b and the conduction band 31b and flows into the n+ layer 7b serving as the third impurity layer. At this time, hole groups 11 are generated. As indicated by reference numeral 50, the hole groups 11 flow into the second semiconductor layer 8 and the first semiconductor layer 4, which are floating bodies. This state is illustrated in FIG. 2B.

FIG. 2C illustrates the hole groups 11 in the p layer 4 and the p layer 8 in a write state in which, immediately after the page write operation, the word line WL, the bit line BL, and the source line SL are at 0 V and the plate line PL is at the first voltage. The generated hole groups 11 are the majority carriers of the p layer 4 and the p layer 8. The generated hole concentration is temporarily high in the region of the p layer 8, and the hole groups 11 move toward the p layer 4 by diffusion in accordance with the concentration gradient. In addition, since the first gate conductor layer 22 is made of p+ poly, the hole groups 11 is stored at a higher concentration in a region of the p layer 4, the region being close to the first gate insulating layer 5. As a result, the p layer 4 has a hole concentration higher than the hole concentration of the p layer 8. Since the p layer 4 and the p layer 8 are electrically connected to each other, the p layer 8 serving as the substrate of the MOSFET substantially including the second gate conductor layer 10 is charged to a positive bias. The holes in the depletion layer move toward the source line SL, the bit line BL, or the n layer 3 and are gradually recombined with the electrons. The threshold voltage of the MOSFET including the second gate conductor layer 10 decreases due to the positive substrate-bias effect caused by the holes temporarily stored in the p layer 4 and the p layer 8. Accordingly, as illustrated in FIG. 2D, the threshold voltage of the MOSFET including the second gate conductor layer 10 to which the word line WL is connected decreases. This write state is assigned to logic “1” data.

The voltage conditions to be applied to the bit line BL, the source line SL, the word line WL, the plate line PL, and the bottom line BTL, described above, are an example for performing the write operation, and other voltage conditions under which the write operation can be performed may be used.

In the structure according to the present embodiment, the p layer 8 in the MOSFET including the second gate conductor layer 10 to which the word line WL is connected is electrically connected to the p layer 4. Thus, the capacity for storing generated holes can be freely changed by adjusting the volume of the p layer 4. In other words, for example, the p layer 4 is located at a deeper position to increase the retention time. It is therefore desirable that the bottom portion of the p layer 4 be positioned deeper than the bottom portion of the p layer 8. In addition, the contact areas of the n layer 3, the n+ layer 7a, and the n+ layer 7b, which are involved in recombination with electrons, can be intentionally made smaller than the volume of the region where the hole carriers are stored, namely, the volumes of the p layer 4 and the p layer 8. Thus, the recombination with electrons is less likely to occur, resulting in an increase in the time of retention of the stored holes. Furthermore, since the first gate conductor layer 22 is made of p+ poly, the stored holes are accumulated in the near-interface region of the p layer 4 serving as the first semiconductor layer, which is in contact with the first gate insulating layer 5. In addition, holes can be stored in regions away from the pn junction regions where the recombination of electrons and holes, which is the cause of loss of data, takes place. In other words, holes can be stored in regions away from the contact regions between the n+ layer 7a and the p layer 8 and between the n+ layer 7b and the p layer 8. As a result, stable storage of holes is achieved. Accordingly, in the memory element, the overall effect of substrate bias is enhanced for the substrate, resulting in an increase in the time of memory retention and an increase in the voltage margin in the write state of the logic “1” data.

In addition, since the gate-induced drain leakage current is used in the page write operation, the DC current between the bit line and the source line is zero. Accordingly, the page write operation can be performed with very low power consumption, and the simultaneous writing of multi-bit memory cells can be achieved.

In the page write operation, instead of the gate-induced drain leakage current, a current flowing between the second impurity layer (i.e., the n+ layer 7a) and the third impurity layer (i.e., the n+ layer 7b) may cause an impact ionization phenomenon to occur near the third impurity layer (i.e., the n+ layer 7b) to generate the hole groups 11, and the hole groups 11 may be caused to flow into the second semiconductor layer 8 and the first semiconductor layer 4, which are floating bodies (see Takashi Ohasawa and Takeshi Hamamoto, “Floating Body Cell—a Novel Body Capacitorless DRAM Cell”, Pan Stanford Publishing (2011)).

Next, a mechanism for a page erase operation will be described with reference to FIGS. 3A to 3C. FIG. 3A illustrates a state immediately after the hole groups 11 in the write state in the previous cycle are stored in the p layer 4 and the p layer 8, the word line WL, the bit line BL, and the source line SL are at 0 V, and the plate line PL is at the ground voltage or the first negative voltage prior to the page erase operation. As illustrated in FIG. 3B, at the time of the page erase operation, the voltage of the plate line PL is set to a first positive voltage, for example, 2 V. As a result, regardless of the value of the initial potential of the p layer 8 serving as the second semiconductor layer, the capacitive coupling between the plate line PL and the first semiconductor layer 4 in the floating state increases the voltages of the first semiconductor layer 4 and the p layer 8 serving as the second semiconductor layer. Accordingly, the PN junction between the p layer 8 serving as the second semiconductor layer and the n+ layer 7a connected to the source line SL and serving as the source and the PN junction between the n+ layer 7b connected to the bit line BL and serving as the drain and the p layer 8 are forward biased. As a result, the hole groups 11 stored in the p layer 4 and the p layer 8 in the previous cycle move to the n+ layer 7a connected to the source line SL and to the n+ layer 7b connected to the bit line BL. Further, as a result of application of a voltage of 2 V to the plate line PL, an inversion layer 14 is formed at the interface between the first gate insulating layer 5 and the p layer 4 and comes into contact with the n layer 3 connected to the bottom line BTL. Accordingly, the holes stored in the p layer 4 flow from the p layer 4 to the n layer 3 or the inversion layer 14 and are recombined with the electrons. As a result, the hole concentrations of the p layer 4 and the p layer 8 decrease with time, and the threshold voltage of the MOSFET becomes higher than that in the write state of the logic “1” data, resulting in an erase state. Thus, as illustrated in FIG. 3C, the MOSFET including the second gate conductor layer 10 to which the word line WL is connected has a threshold of the erase state. The erase state of the dynamic flash memory is assigned to logic “0” data.

In the structure according to the present embodiment, during data erasing, the electron-hole recombination area can be effectively increased compared with during data storage. Thus, the state in which the logic “0” data remains stable can be provided in a short time, and the operation speed of the dynamic flash memory element is increased.

The voltage conditions to be applied to the bit line BL, the source line SL, the word line WL, the plate line PL, and the bottom line BTL, described above, is an example for performing the erase operation, and other voltage conditions under which the erase operation can be performed may be used. For example, in the foregoing description, the first gate conductor layer 22 is biased to 2 V, by way of example. During erasing, for example, the bit line BL is biased to 0.2 V, the source line SL is biased to 0 V, and the first gate conductor layer 22 and the second gate conductor layer 10 are biased to 2 V. As a result, inversion layers in which electrons are the majority carriers can be formed at the interface between the p layer 8 and the second gate insulating layer 9 and at the interface between the p layer 4 and the first gate insulating layer 5, thereby increasing the electron-hole recombination area. In addition, a current with electrons as the majority carriers is caused to flow between the bit line BL and the source line SL, thereby making it possible to further actively reduce the erase time.

In the present embodiment, the p layer 8, which is one of the constituent elements of the MOSFET for reading and writing information, is electrically connected to the p layer 1, the n layer 3, and the p layer 4. Furthermore, a certain voltage can be applied to the first gate conductor layer 22. Thus, in both the write operation and the erase operation, unlike a silicon on insulator (SOI) structure, for example, instability of the substrate bias in the floating state does not occur during operation of the MOSFET, and a complete depletion of the semiconductor region under the second gate insulating layer 9 does not occur. For this reason, the threshold, the drive current, and the like of the MOSFET are less likely to be affected by the operation state. Thus, the properties of the MOSFET, namely, the thickness, the type of the impurity, the impurity concentration, and the profile of the p layer 8, the impurity concentration and the profile of the p layer 4, the thickness and the material of the second gate insulating layer 9, and the work functions of the gate conductor layers 10 and 22, can be adjusted to set voltages for desired memory operations in a wide range. In addition, the region under the MOSFET is not completely depleted and a depletion layer extends in the depth direction of the p layer 4. Thus, in the floating body, coupling of the gate electrode due to the word line, which is a drawback of a capacitor-less DRAM, does not substantially affect the MOSFET. In other words, according to the present embodiment, the dynamic flash memory can be designed to have a wide margin of operating voltages.

Further, in the page erase operation, the large capacitive coupling between the first gate conductor layer 22 and the first semiconductor layer 4 can raise the voltage of the first semiconductor layer 4. As a result, the PN junction between the second impurity layer 7a and the second semiconductor layer 8, the PN junction between the third impurity layer 7b and the second semiconductor layer 8, and the PN junction between the first impurity layer 3 and the first semiconductor layer 4 can be easily forward biased.

In addition, the present embodiment has the advantage of preventing malfunction of a memory cell. One of the issues in the operation of memory cells is that control of the voltage of a target cell results in unnecessary application of voltages to electrodes of some cells other than the target cell in a cell array, leading to malfunction (for example, Takashi Ohasawa and Takeshi Hamamoto, “Floating Body Cell—a Novel Body Capacitorless DRAM Cell”, Pan Stanford Publishing (2011)). Specifically, the following phenomenon occurs. In a memory cell in which the logic “1” data is written, the logic “1” data is changed to the logic “0” data in response to the operation of another memory cell. In a memory cell in which the logic “0” data is written, the logic “0” data is changed to the logic “1” data in response to the operation of another memory cell. This phenomenon is hereafter referred to as disturb failure. In the present embodiment, when the logic “1” data is initially written as data information, the number of stored holes can be increased with respect to the amount of recombination of electrons and holes generated by a transistor operation, by adjusting the depth of the p layer 4. Even in a condition under which disturb failure occurs in an existing memory, the number of stored holes is less likely to affect changes in the threshold of the MOSFET, and a failure is less likely to occur. When the logic “0” data is initially written as data information, even in a case where holes are unintentionally generated by a transistor operation during reading, the holes are immediately diffused into the p layer 4. Thus, the depth of the p layer 4 is increased to reduce the rate of change in the overall hole concentration of the p layer 4 and the p layer 8. Also in this case, the unintentional generation of the holes is less likely to affect the threshold of the MOSFET, and the probability of the occurrence of disturb failure can be reduced compared with existing memories. Therefore, the present embodiment provides a memory cell having a structure resistant to disturb failure.

When data information is the logic “0” data, the logic data may be changed from “0” to “1” in response to storage of holes in the p layer 8 among the hole-electron pairs generated in the depletion layer of the memory cell at the time of data retention. In the structure according to the embodiment of the present invention, however, holes are stored at a higher concentration in the p layer 4 and do not greatly affect changes in the hole concentration of the p layer 8 disposed directly under the MOSFET. As a result, the information of the logic “0” data can stably be retained.

As is apparent from the structure illustrated in FIG. 1A and FIGS. 1BA to 1BC, the formation of the element structure including the p layer 8, the n+ layers 7a and 7b, the second gate insulating layer 9, and the second gate conductor layer 10 may be performed not only for the memory cell but also for other MOS circuits including typical CMOS structures. Accordingly, the memory cell can be easily combined with existing CMOS circuits.

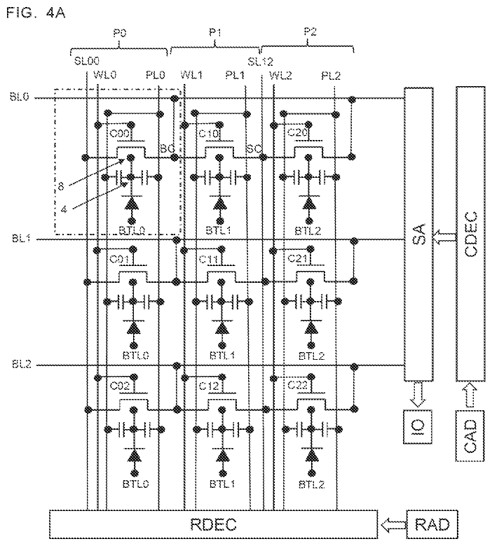

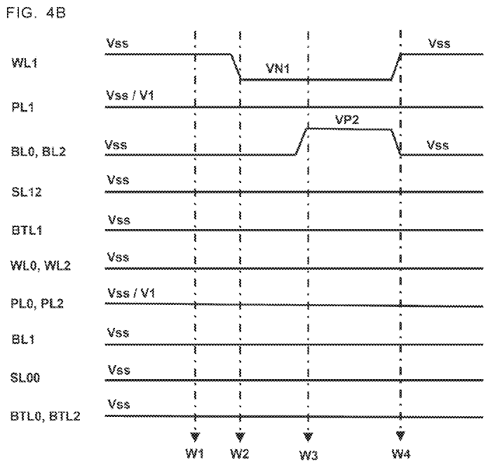

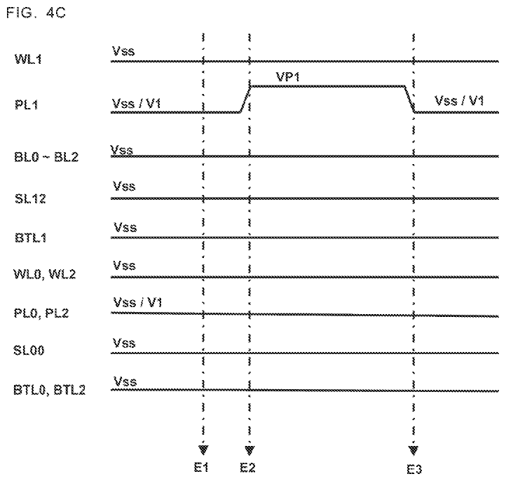

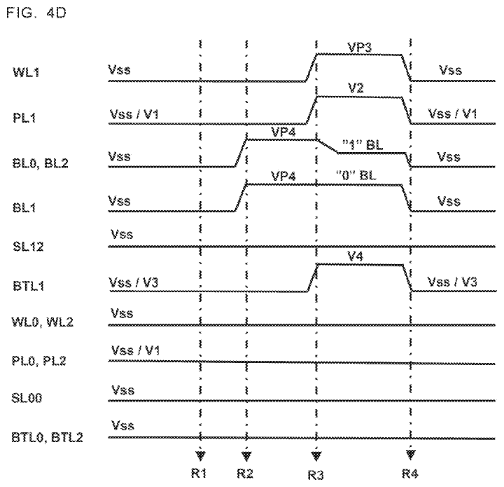

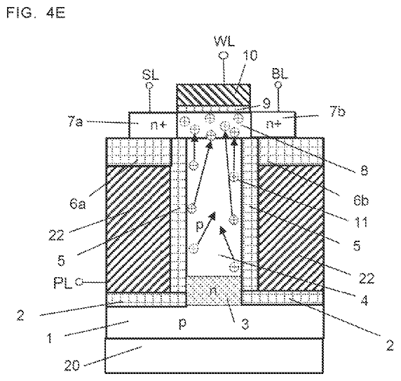

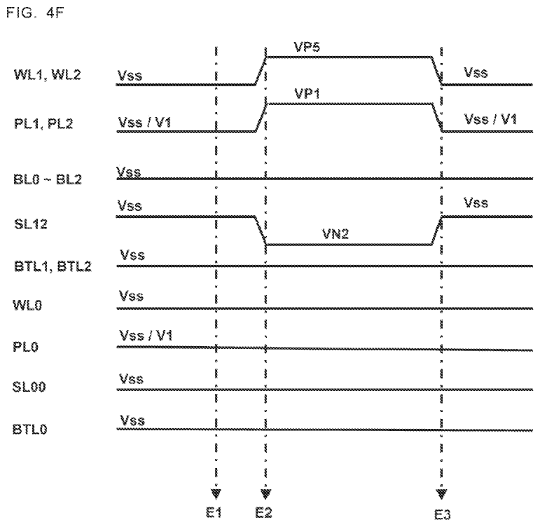

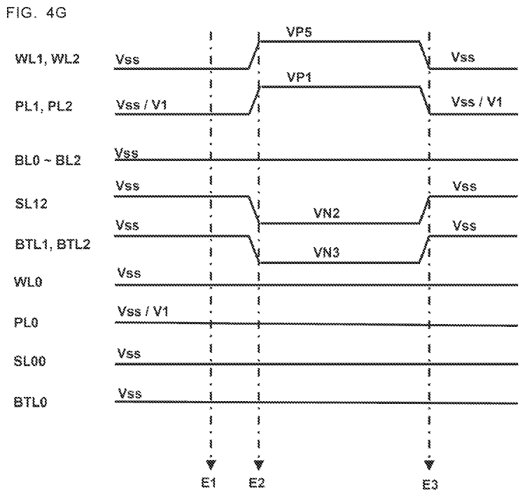

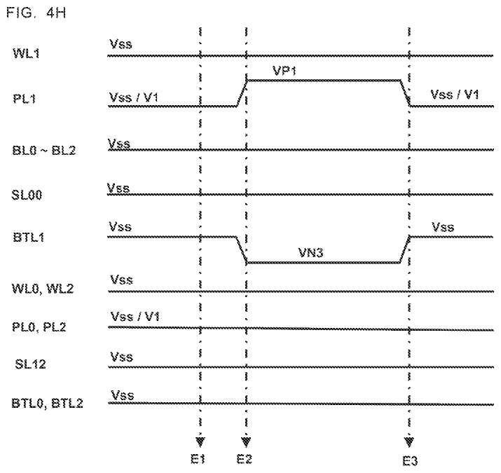

A page write operation, a page erase operation, and a page read operation of the dynamic flash memory according to the present embodiment will be described with reference to FIGS. 4A to 4H.

FIG. 4A is a block diagram of a memory cell array including a main circuit. Word lines WL0 to WL2, plate lines PL0 to PL2, and source lines SL00 and SL12 are connected to a row decoder circuit RDEC. Bottom lines BTL0 to BTL2 are also connected to the row decoder circuit RDEC (wiring for connection therebetween is not illustrated). In response to receipt of a row address RAD as an input, the row decoder circuit RDEC selects any one of pages P0 to P2 in accordance with the row address RAD. Further, bit lines BL0 to BL2 are orthogonal to the word lines WL0 to WL2, the plate lines PL0 to PL2, the source lines SL00 and SL12, and the bottom lines BTL0 to BTL2 and are connected to a sense amplifier circuit SA. The sense amplifier circuit SA is connected to a column decoder circuit CDEC, and the column decoder circuit CDEC receives a column address CAD as an input. The sense amplifier circuit SA is selectively connected to an input/output circuit IO in accordance with the column address CAD.

In the memory cell array illustrated in FIG. 4A, one memory cell is indicated by a region surrounded by a dot-dash line and corresponds to the memory cell illustrated in FIG. 1A and FIGS. 1BA to 1BC. In the correspondences, specifically, in FIG. 1A and FIGS. 1BA to 1BC, the second gate conductor layer 10 is connected to the word line WL, the first gate conductor layer 22 is connected to the plate line PL, the second impurity layer (n+ layer) 7a is connected to the source line SL, the third impurity layer (n+ layer) 7b is connected to the bit line BL, and the first impurity layer (n layer) 3 is connected to the bottom line BTL. In FIG. 4A, memory cells C00 to C22 arranged in an array of three rows and three columns, that is, nine memory cells in total, are illustrated in plan view. An actual memory cell array includes a larger number of memory cells. When memory cells are arranged in an array of rows and columns, one direction of the array is referred to as a “row direction”, and a direction perpendicular to the row direction is referred to as a “column direction”. In plan view, the source lines SL00 and SL12, the bottom lines BTL0 to BTL2, the plate lines PL0 to PL2, and the word lines WL0 to WL2 are disposed in parallel in the “row direction” to form a plurality of pages. The bit lines BL0 to BL2 are disposed in a direction perpendicular to the source lines SL00 and SL12, the bottom lines BTL0 to BTL2, the plate lines PL0 to PL2, and the word lines WL0 to WL2. For example, in the illustrated memory cell array, selection of a page P1 means selection of the memory cells C10 to C12, which are connected to the plate line PL1, the word line WL1, the source line SL12, and the bottom line BTL1.

In FIG. 4A, in the memory cells C10 and C20, impurity layers each corresponding to the second impurity layer 7a illustrated in FIG. 1A and FIGS. 1BA to 1BC, are connected to each other by wiring. Further, the memory cells C00 and C10 share an impurity layer corresponding to the third impurity layer 7b illustrated in FIG. 1A and FIGS. 1BA to 1BC.

The page write operation will be described with reference to an operation waveform diagram illustrated in FIG. 4B. A first write time W1 indicates the voltage states of respective nodes before the page write operation. A ground voltage Vss is applied to the word lines WL0 to WL2. The ground voltage Vss or a first voltage V1 is applied to the plate lines PL0 to PL2 as a voltage to be applied at the time of data retention. The ground voltage Vss is applied to the bit lines BL0 to BL2. The ground voltage Vss is applied to the source lines SL00 and SL12. The ground voltage Vss is applied to the bottom lines BTL0 to BTL2. The ground voltage Vss is, for example, 0 V. The first voltage V1 is, for example, −1 V.

At a second write time W2, the word line WL1 of the page P1 is selected, and the voltage drops from the ground voltage Vss to a first negative voltage VN1. The first negative voltage VN1 is, for example, −1 V, which is the same as the first voltage V1. At a third write time W3, the voltages of the bit lines BL0 and BL2 rise from the ground voltage Vss to a second positive voltage VP2, based on the write page data stored (loaded) in the sense amplifier circuit SA in advance, assuming that, for example, the bit lines BL0 and BL2 are bit lines for writing the logic “1” data and the bit line BL1 is a bit line for retaining the logic “0” data (the page is erased in the previous cycle). As a result, the high electric field between the second gate conductor layer 10 and the third impurity layer 7b of each of the memory cells C10 and C12 generates a gate-induced drain leakage (GIDL) current, and a hole group 11 is stored in the second semiconductor layer 8. In the memory cells C10 and C12, the logic “0” data is rewritten to the logic “1” data. At a fourth write time W4, the voltage of the selected word line WL1 rises from the first negative voltage VN1 to the ground voltage Vss, and the voltages of the bit lines BL0 and BL2 fall from the second positive voltage VP2 to the ground voltage Vss. Then, the page write operation ends.

The page erase operation will be described with reference to an operation waveform diagram illustrated in FIG. 4C. A first erase time E1 indicates the voltage states of respective nodes before the page erase operation. The ground voltage Vss is applied to the word lines WL0 to WL2. The ground voltage Vss or the first voltage V1 is applied to the plate lines PL0 to PL2 as a voltage to be applied at the time of data retention. The ground voltage Vss is applied to the bit lines BL0 to BL2. The ground voltage Vss is applied to the source lines SL00 and SL12. The ground voltage Vss is applied to the bottom lines BTL0 to BTL2. The ground voltage Vss is, for example, 0 V. The first voltage V1 is, for example, −1 V.

At a second erase time E2, the plate line PL1 of the page P1 is selected, and the voltage rises from the ground voltage Vss or the first voltage V1 to a first positive voltage VP1. The first positive voltage VP1 is, for example, 2 V. At this time, the source line SL12 and the bit lines BL0 to BL2 are at the ground voltage Vss. Thus, the capacitive coupling between the plate line PL1 and the first semiconductor layer 4 of each of the memory cells C10, C11 and C12 belonging to the page P1 increases the voltage of the first semiconductor layer 4 in the floating state. As a result, in each of the memory cells C10, C11, and C12, the logic “1” data is written by the page write operation in the previous cycle, and hole groups 11 are stored in the first semiconductor layer 4 and the second semiconductor layer 8. The PN junction between the second impurity layer 7a and the second semiconductor layer 8, the PN junction between the third impurity layer 7b and the second semiconductor layer 8, and the PN junction between the first impurity layer 3 and the first semiconductor layer 4 are forward biased, and the hole groups 11 disappear. Also in a case where the logic “0” data is maintained in the memory cells C10, C11, and C12 in the previous cycle, the hole groups 11 that remain disappear. In other words, all the memory cells C10, C11, and C12 belonging to the page P1 are subjected to the page erase operation and store the logic “0” data. At a third erase time E3, the voltage of the selected plate line PL1 falls from the first positive voltage VP1 to the ground voltage Vss or the first voltage V1, and the page erase operation ends.

The page read operation will be described with reference to an operation waveform diagram illustrated in FIG. 4D. A first read time R1 indicates the voltage states of respective nodes before the page read operation. The ground voltage Vss is applied to the word lines WL0 to WL2. The ground voltage Vss or the first voltage V1 is applied to the plate lines PL0 to PL2 as a voltage to be applied at the time of data retention. The ground voltage Vss is applied to the bit lines BL0 to BL2. The ground voltage Vss is applied to the source lines SL00 and SL12. The ground voltage Vss or a third voltage V3 is applied to the bottom lines BTL0 to BTL2. The ground voltage Vss is, for example, 0 V. The first voltage V1 is, for example, −1 V. The third voltage V3 is, for example, 0 V.

At a second read time R2, the voltages of the bit lines BL0 to BL2 rise from the ground voltage Vss to a fourth positive voltage VP4 by load transistor circuits disposed for the bit lines BL0 to BL2. The load transistor circuits are not illustrated in the drawings. At a third read time R3, the word line WL1 of the page P1 is selected, and the voltage rises from the ground voltage Vss to a third positive voltage VP3. The third positive voltage VP3 is, for example, 1.5 V. Further, the voltage of the plate line PL1 rises from the ground voltage Vss or the first voltage V1 to a second voltage V2, and the voltage of the bottom line BTL1 rises from the ground voltage Vss or the third voltage V3 to a fourth voltage V4. The second voltage V2 is, for example, 1 V. The fourth voltage V4 is, for example, 1 V.

It is assumed that, for example, the data stored in the memory cells C10 and C12 is the logic “1” data and the data stored in the memory cell C11 is the logic “0” data. As a result, in each of the memory cells C10 and C12, as illustrated in FIG. 4E, some of the hole groups 11, which are the majority carriers in the first semiconductor layer 4, move from the first semiconductor layer 4 to the second semiconductor layer 8. Accordingly, the hole groups 11 are collected in the second semiconductor layer 8. Due to the substrate-bias effect, the threshold voltage of the MOSFET of each of the memory cells C10 and C12, including, as constituent elements, the n+ layer 7a serving as the source, the n+ layer 7b serving as the drain, the second gate insulating layer 9, the second gate conductor layer 10 serving as the gate, and the p layer 8 serving as the substrate, decreases, and a memory cell current flows. Accordingly, when the sense amplifier circuit SA is designed by a static current sense method, the current values of the load transistor circuits compete with the memory cell current values, and the voltages of the bit lines BL0 and BL2 are set to voltage “1” BL, which is lower than that of a bit line for reading the logic “0” data. When the sense amplifier circuit SA is designed by a dynamic sense method, which is similar to that of a DRAM, the bit lines BL0 and BL2 are set to the ground voltage Vss. In the memory cell C11 in which the logic “0” data is stored, by contrast, the hole groups 11 are not collected in the second semiconductor layer 8, and the voltage of the bit line BL1 remains unchanged, with the fourth positive voltage VP4 maintained.

According to an embodiment of the present invention, in each of the memory cells C10 and C12 in which the logic “1” data is stored, some of the hole groups 11, which are the majority carriers in the first semiconductor layer 4, are allowed to move from the first semiconductor layer 4 to the second semiconductor layer 8 at the time of the page read operation. Thus, miniaturization of the MOSFET of a memory cell can be achieved. As a result, the MOSFET of a memory cell may be implemented as a highly integrated fine MOSFET such as a FinFET, a Nanosheet transistor, or a GAA transistor.

At a fourth read time R4, the voltage of the selected word line WL1 falls from the third positive voltage VP3 to the ground voltage Vss, the voltage of the plate line PL1 falls from the second voltage V2 to the ground voltage Vss or the first voltage V1, the voltage of the bottom line BTL1 falls from the fourth voltage V4 to the ground voltage Vss or the third voltage V3, the voltages of the bit lines BL0 and BL2 fall from the voltage “1” BL for reading the logic “1” data to the ground voltage Vss, and the voltage of the bit line BL1 falls from the voltage “0” BL for reading the logic “0” data, that is, the fourth positive voltage VP4, to the ground voltage Vss. Then, the page read operation ends.

As illustrated in an operation waveform diagram illustrated in FIG. 4F, in the page erase operation, at the second erase time E2, a second negative voltage VN2 may be applied to the source line SL12 to simultaneously erase two pages, namely, the pages P1 and P2. The second negative voltage VN2 is, for example, −0.7 V. At this time, setting the voltages of the word lines WL1 and WL2 to a fifth positive voltage VP5 provides more effective erasing. The fifth positive voltage VP5 is, for example, 1 V.

As illustrated in an operation waveform diagram illustrated in FIG. 4G, in the page erase operation, at the second erase time E2, a third negative voltage VN3 may be applied to the bottom lines BTL1 and BTL2 to simultaneously erase two pages, namely, the pages P1 and P2. The third negative voltage VN3 is, for example, −0.7 V. At this time, applying the second negative voltage VN2 to the source line SL12 and setting the voltages of the word lines WL1 and WL2 to the fifth positive voltage VP5 provide more effective erasing.

As illustrated in an operation waveform diagram illustrated in FIG. 4H, in the page erase operation, at the second erase time E2, the third negative voltage VN3 may be applied to the bottom line BTL1 to perform a page erase operation for the page P1. As a result, the erase operation for a single page can be performed.

The present embodiment has the following features.

### Feature 1

In the dynamic flash memory according to the first embodiment of the present invention, in a memory cell in which the logic “1” data is stored, some of the hole groups 11, which are the majority carriers in the first semiconductor layer 4, are allowed to move from the first semiconductor layer 4 to the second semiconductor layer 8 in the page read operation. As a result, even in the case of miniaturization of the MOSFET of the memory cell, the hole groups 11 can be easily collected in the second semiconductor layer 8. Thus, the MOSFET of the memory cell may be implemented as a highly integrated fine MOSFET such as a FinFET, a Nanosheet transistor, or a GAA transistor, and a large-capacity dynamic flash memory can be provided at low cost.

### Feature 2

In the page erase operation, the capacitive coupling between the first gate conductor layer 22 and the first semiconductor layer 4 can raise the voltage of the first semiconductor layer 4. As a result, the PN junction between the second impurity layer 7a and the second semiconductor layer 8, the PN junction between the third impurity layer 7b and the second semiconductor layer 8, and the PN junction between the first impurity layer 3 and the first semiconductor layer 4 can be forward biased. Accordingly, in a memory cell in which the logic “1” data is written by the page write operation, the hole groups 11 stored in the first semiconductor layer 4 and the second semiconductor layer 8 can efficiently be made to disappear.

### Feature 3

In the dynamic flash memory according to the first embodiment of the present invention, the substrate region in which the channel of the MOSFET is formed includes the p layer 8 and the p layer 4 surrounded by the first insulating layer 2, the first gate insulating layer 5, and the n layer 3. This structure allows the majority carriers generated during writing of logic “1” to be stored in the p layer 8 and the player 4, with the number of majority carriers being increased. This structure further allows the holes generated during writing to be stored near the interface of the p layer 4 in the vicinity of the first gate conductor layer 22, with the information retention time being increased. At the time of data erasing, a positive voltage is applied to the first gate conductor layer 22 to form an inversion layer to effectively increase the electron-hole recombination area. Accordingly, the area of recombination with electrons is increased, and the erasing time is shortened. In addition, a negative voltage is applied to the n+ layer 7a connected to the source line SL, thereby accelerating the erase operation by the thyristor structure of the n+ layer 7a, the p layer 8, the p layer 4, the n layer 3, and the p layer 1. Accordingly, the operation margin of the memory can be increased, and power consumption can be reduced, leading to the high-speed operations of the memory.

### Feature 4

In the dynamic flash memory according to the first embodiment of the present invention, the p layer 8, which is one of the constituent elements of the MOSFET, is connected to the p layer 4, the n layer 3, and the p layer 1, and the voltage to be applied to the first gate conductor layer 22 is adjusted to prevent complete depletion of the p layer 8 and the p layer 4 under the second gate insulating layer 9. For this reason, the threshold, the drive current, and the like of the MOSFET are less likely to be affected by the operation state of the memory. In addition, the region under the MOSFET is not completely depleted. Thus, in the floating body, coupling of the gate electrode due to the word line, which is a drawback of a capacitor-less DRAM, does not greatly affect the MOSFET. In other words, according to an embodiment of the present invention, the dynamic flash memory can be designed to have a wide margin of operating voltages.

In FIG. 1A and FIGS. 1BA to 1BC, a dynamic flash memory element has been described in terms of an SGT including the first gate conductor layer 22 and the first gate insulating layer 5 surrounding an entire side surface of the first semiconductor layer 4 standing on a substrate in a direction perpendicular to the substrate, by way of example. As described above, the dynamic flash memory element according to the present embodiment desirably has a structure satisfying the condition that the hole groups 11 generated by the gate-induced drain leakage current are retained in the first semiconductor layer 4 and the second semiconductor layer 8. To achieve this structure, the first semiconductor layer 4 and the second semiconductor layer 8 have a floating body structure electrically separated from the substrate 20. Accordingly, even in a case where the semiconductor base bodies of the first semiconductor layer 4 and the second semiconductor layer 8 are formed horizontally with respect to the substrate 20 (with the center axes of the semiconductor base bodies parallel to the substrate 20) by using, for example, gate-all-around (GAA) technology or Nanosheet technology, which is one of the SGT Technologies, the dynamic flash memory operation described above can be performed. Alternatively, a structure may be employed in which a plurality of GAA transistors or Nanosheet transistors formed in the horizontal direction are stacked on top of each other. Alternatively, a device structure based on silicon on insulator (SOI) technology may be employed. In this device structure, a channel region has a bottom portion that is in contact with an insulating layer of an SOI substrate, and another channel region is surrounded by a gate insulating layer and an element isolation insulating layer. Also in this structure, the channel regions have a floating body structure. As described above, the dynamic flash memory element provided in the present embodiment desirably satisfies the condition that the channel regions have a floating body structure. Even in a structure in which a FinFET is formed on an SOI substrate, the dynamic flash memory operation described above can be performed as long as the channel regions have a floating body structure.

Various embodiments and modifications may be made to the present invention without departing from the broad spirit and scope of the present invention. The embodiments described above are for describing an example of the present invention, and do not limit the scope of the present invention. The embodiments and modifications described above may be combined as desired. Some of the components of the embodiments described above may be removed as necessary to provide other embodiments, and such embodiments are also within scope of the technical idea of the present invention.

According to a semiconductor-element-including memory device according to an embodiment of the present invention, a high-speed dynamic flash memory that provides longer-term storage with lower power consumption than existing ones can be provided.

What is claimed is:

1. A semiconductor-element-including memory device comprising:
a memory cell array, the memory cell array including a plurality of pages connected to a bit line disposed on a substrate in a column direction in plan view, each of the plurality of pages including a plurality of memory cells arranged on the substrate in a row direction in plan view, wherein
each of the memory cells included in each of the plurality of pages includes:
a first impurity layer on top of the substrate;
a first insulating layer covering the substrate and a portion of the first impurity layer;
a first semiconductor layer having a pillar shape and extending in a direction perpendicular to the first impurity layer in contact with the first impurity layer;
a first gate insulating layer surrounding the first semiconductor layer;
a first gate conductor layer covering the first gate insulating layer;
a second insulating layer on top of the first gate conductor layer;
a second semiconductor layer on top of and in contact with the first semiconductor layer;
a second gate insulating layer surrounding at least a top portion of the second semiconductor layer;
a second gate conductor layer covering the second gate insulating layer;
a second impurity layer; and
a third impurity layer,
the second impurity layer and the third impurity layer being connected to both ends of the second semiconductor layer in a horizontal direction in which the second semiconductor layer extends, the both ends of the second semiconductor layer being outside one end of the second gate conductor layer,
in a page erase operation, majority carriers remaining in the first semiconductor layer or the second semiconductor layer are extracted by being recombined with majority carriers in the first impurity layer, the second impurity layer, and the third impurity layer,
in a page write operation,
an electron group and a hole group are generated in the second semiconductor layer and the first semiconductor layer by using a gate-induced drain leakage current or by using an impact ionization phenomenon caused by a current flowing between the second impurity layer and the third impurity layer, and
an operation of causing some or all of majority carriers in the second semiconductor layer and the first semiconductor layer to remain in the second semiconductor layer and the first semiconductor layer is performed, and
in a page read operation, an operation of causing some of the majority carriers in the second semiconductor layer and the first semiconductor layer to move from the first semiconductor layer to the second semiconductor layer is performed to determine an erase state or a write state of the memory cell, based on a magnitude of a memory cell current between the bit line and a source line of the memory cell.

2. The semiconductor-element-including memory device according to claim 1, wherein
the second impurity layer is connected to the source line,
the third impurity layer is connected to the bit line,
the second gate conductor layer is connected to a word line, and
the first gate conductor layer is connected to a plate line.

3. The semiconductor-element-including memory device according to claim 2, wherein
the page erase operation, the page write operation, and the page read operation are performed by controlling voltages to be applied to the source line, the bit line, the word line, and the plate line.

4. The semiconductor-element-including memory device according to claim 2, wherein
a first voltage is applied to the plate line at a time of retention of data in the memory cell, and
a second voltage higher than the first voltage is applied to the plate line at a time of the page read operation.

5. The semiconductor-element-including memory device according to claim 4, wherein
a ground voltage is applied to the source line, the bit line, and the word line at the time of retention of data in the memory cell.

6. The semiconductor-element-including memory device according to claim 2, wherein
in the page erase operation, a first positive voltage is applied to the plate line.

7. The semiconductor-element-including memory device according to claim 2, wherein
in the page write operation, a first negative voltage is applied to the word line.

8. The semiconductor-element-including memory device according to claim 1, wherein
in the page write operation, a second positive voltage is applied to the bit line.

9. The semiconductor-element-including memory device according to claim 2, wherein
in the page read operation, a third positive voltage is applied to the word line, and a fourth positive voltage is applied to the bit line.

10. The semiconductor-element-including memory device according to claim 1, wherein
a vertical distance from a bottom portion of the second semiconductor layer to a top portion of the first impurity layer is shorter than a vertical distance from the bottom portion of the second semiconductor layer to a bottom portion of the first gate conductor layer.

11. The semiconductor-element-including memory device according to claim 1, wherein
the source line connected to the second impurity layer of one of the plurality of memory cells is shared with the second impurity layer of an adjacent memory cell of the plurality of memory cells.

12. The semiconductor-element-including memory device according to claim 1, wherein
the bit line connected to the third impurity layer of one of the plurality of memory cells is shared with the third impurity layer of an adjacent memory cell of the plurality of memory cells.

13. The semiconductor-element-including memory device according to claim 5, wherein
the ground voltage is zero volts.

14. The semiconductor-element-including memory device according to claim 1, wherein
a bottom portion of the first impurity layer is not at a same level as a bottom portion of the first insulating layer, and
the first impurity layer is shared by the plurality of memory cells.

15. The semiconductor-element-including memory device according to claim 2, wherein
a bottom line is connected to the first impurity layer, and a desired voltage is applicable to the bottom line.

16. The semiconductor-element-including memory device according to claim 2, wherein
in the page erase operation, a second negative voltage is applied to the source line, and a fifth positive voltage is applied to the word line.

17. The semiconductor-element-including memory device according to claim 15, wherein
in the page erase operation, a third negative voltage is applied to the bottom line.

18. The semiconductor-element-including memory device according to claim 15, wherein
a third voltage is applied to the bottom line at a time of retention of data in the memory cell, and
a fourth voltage higher than the third voltage is applied at a time of the page read operation.

19. The semiconductor-element-including memory device according to claim 17, wherein
the source line, the word line, the plate line, and the bottom line are arranged in parallel in the row direction and are included in each of the plurality of pages, and the bit line arranged in the column direction is orthogonal to the page.

20. The semiconductor-element-including memory device according to claim 1, wherein
in the page write operation, a DC current between the bit line and the source line is zero.

21. The semiconductor-element-including memory device according to claim 1, wherein
in the page erase operation, capacitive coupling between the first gate conductor layer and the first semiconductor layer raises a voltage of the first semiconductor layer.
